(19) United States
(12) Patent Application Publication
(10) Pub. No.: US 2009/0195285 A1
(43) Pub. Date: Aug. 6, 2009

(54) SEMICONDUCTOR INTEGRATED CIRCUIT

(75) Inventors: Hisao Kamiya, Osaka (JP); Motohiro Ohki, Osaka (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/301,422

(22) PCT Filed: Dec. 14, 2006
(86) PCT No.: PCT/JP2006/324957

§ 371 Date: Nov. 18, 2008

(30) Foreign Application Priority Data
Jun. 5, 2006 (JP) 2006-155695

(51) Int. Cl. H03K 3/00

(52) U.S. Cl. 327/218

(57) ABSTRACT

A semiconductor integrated circuit is provided with one or more flip-flop circuits (10a and 10b) and a control signal generating section (20). The control signal generating section (20) outputs a control signal to control ON/OFF of the flip-flop circuits (10a and 10b). Each of the flip-flop circuits (10a and 10b) operates by receiving the clock signal and the control signal output from the control signal generating section (20).

### TECHNICAL FIELD

The present invention relates to a semiconductor integrated circuit, specifically to a semiconductor integrated circuit provided with a plurality of circuits having different operating conditions.

### BACKGROUND ART

As the integration degree of a semiconductor integrated circuit increases, it becomes important to reduce power consumption in the semiconductor integrated circuit. In a conventional semiconductor integrated circuit, for modules each including circuits collected by function, the necessity of supplying a clock signal is determined module by module, and the supplying a clock signal to a module whose operation is not required is stopped to reduce the power consumption (for example, see Patent Document 1).

### [Patent Document 1] Japanese Published Unexamined Patent Application No. 2000-148284

### DISCLOSURE OF INVENTION

### Problems to be Solved by the Invention

According to the above-mentioned art, supplying/stopping a clock signal is controlled module by module. Therefore, as the number of modules increases, the number of clock trees also increases. This may complicate designing a circuit and increase the man-hour required for designing a semiconductor integrated circuit.

In view of the above-mentioned problems, an object of the present invention is to provide a semiconductor integrated circuit whose power consumption is reduced without increasing the number of clock trees.

### Means for Solving the Problems

To achieve the above-mentioned object, a semiconductor integrated circuit according to the present invention includes: one or more flip-flop circuits each having a logic circuit for receiving a clock signal and a control signal and performing a logical operation on the clock signal and the control signal and a latch circuit for latching an input signal in synchronization with an output of the logic circuit; and a control signal generating section for generating the control signal.

With this configuration, the input signal is latched by the latch circuit in synchronization with the output of the logic circuit to which the clock signal and the control signal are input. Moreover, the control signal generated in the control signal generating section makes it possible to easily control validity/invalidity of the clock signal input to the flip-flop circuits. Therefore, setting the control signal to a predetermined logic level makes the clock signal invalid, allowing the latch circuit to be turned off, so that it is possible to reduce the power consumption. Moreover, since the clock signal is directly input to the logic circuit, the number of clock trees does not increase.

Specifically, the control signal generating section includes: a transition detecting circuit for receiving the input signal and outputting a transition detecting signal showing that the logic level of the input signal is transitioned; and a set/reset circuit which is set by the transition detecting signal output from the transition detecting circuit and which is reset by a reversed phase of the clock signal input to the logic circuit to output the control signal. With this configuration, the operation of the latch circuit is allowed only when the logic level of the input signal transitions. Therefore, it is possible to keep the power consumption to the minimum.

Preferably, the semiconductor integrated circuit further includes: a fuse provided between the logic circuit and the control signal generating section; and a resistor connected between a reference voltage node and a point connecting the fuse to the logic circuit. With this configuration, blowing the fuse can turn off the operation of the latch circuit provided downstream thereof.

More preferably, the semiconductor integrated circuit further includes an antifuse connected parallel to the fuse. With this configuration, even in the case where transmission of the control signal is once shut off by blowing the fuse, it is possible to reconnect the transmission of the control signal.

### EFFECTS OF THE INVENTION

As mentioned above, the present invention makes it possible to reduce the power consumption in the semiconductor integrated circuit especially without increasing the number of clock trees.

### BRIEF DESCRIPTION OF DRAWINGS

FIG. 1 is a view showing a configuration of a semiconductor integrated circuit according to the present invention.

FIG. 2 is a view showing an example of a configuration of a flip-flop circuit.

FIG. 3 is a view showing an example of a configuration of a control signal generating section.

FIG. 4 is a timing chart of the semiconductor integrated circuit according to the present invention.

### DESCRIPTION OF REFERENCE NUMERALS

| | |
|---|---|
| 1 | Semiconductor Integrated Circuit |
| 10a, 10b | Flip-Flop Circuit |
| 11 | AND Circuit (Logic Circuit) |
| 12 | Latch Circuit |
| 20 | Control Signal Generating Section |
| 21 | Transition Detecting Circuit |
| 23 | Set/Reset Circuit |
| 30 | Fuse |
| 40 | Resistor |
| 50 | Antifuse |

### BEST MODE FOR CARRYING OUT THE INVENTION

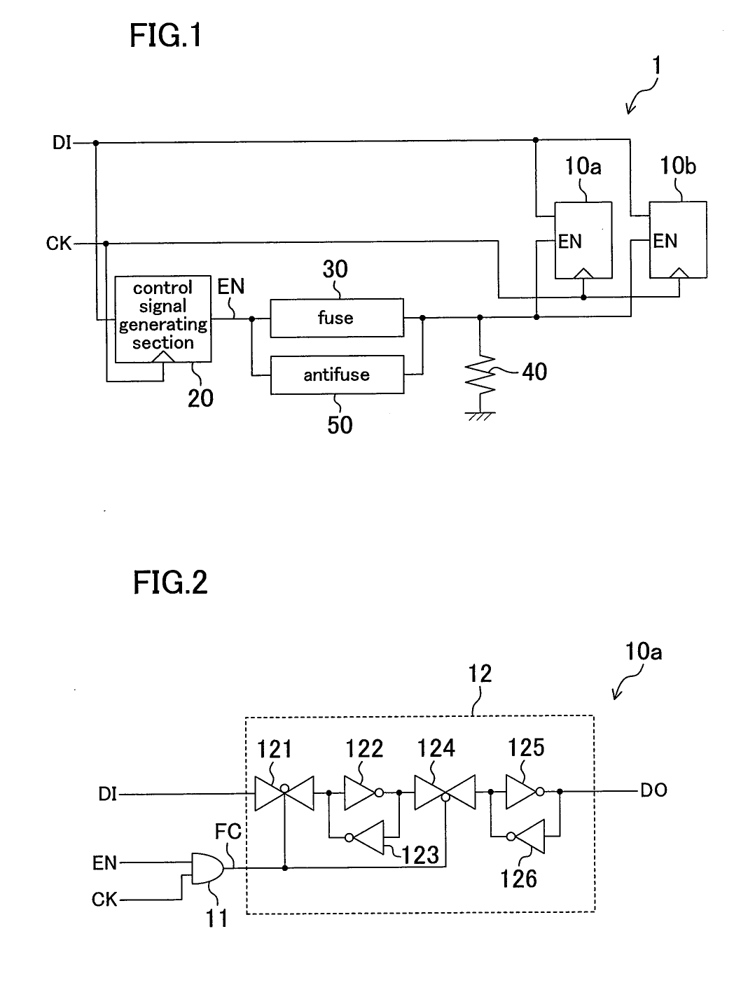

Best mode for carrying out the invention will be described below with reference to the drawings. FIG. 1 shows an example of a configuration of a semiconductor integrated circuit 1 according to the present invention. The semiconductor integrated circuit 1 includes: flip-flop circuits 10a and 10b; a control signal generating section 20; a fuse 30; a resistor 40; and an antifuse 50. For convenience of description, it is assumed that the flip-flop circuits 10a and 10b have the same configuration and are a group of flip-flops having a common function, for example, a test function used for a shipping inspection of circuits.

Each of the flip-flop circuits 10a and 10b receives a control signal EN and a clock signal CK for its operation. FIG. 2 shows an example of a configuration of the flip-flop circuit 10a. The flip-flop circuit 10a includes an AND circuit 11 and a latch circuit 12. The AND circuit 11 receives the control signal EN and the clock signal CK to output a signal FC. The latch circuit 12 includes: a MOS switch 121 which is open when the signal FC output from the AND circuit 11 is “L” and closed when the signal FC is “H”; inverters 122 and 123 which hold a signal transmitted via the MOS switch 121; a MOS switch 124 which is open when the signal FC is “H” and closed when the signal FC is “L”; and inverters 125 and 126 which hold a signal transmitted via the MOS switch 124. It is to be noted that the latch circuit 12 is not limited to the above configuration. The latch circuit 12 may have any configuration, as long as the latch circuit 12 latches an input signal DI in synchronization with the signal FC and outputs an output signal DO.

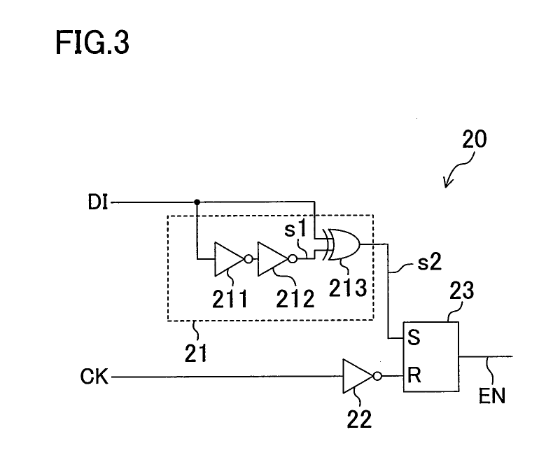

The control signal generating section 20 receives the input signal DI and the clock signal CK to generate the control signal EN. FIG. 3 shows an example of a configuration of the control signal generating section 20. The control signal generating section 20 includes a transition detecting circuit 21, an inverter 22, and a set/reset circuit 23. The transition detecting circuit 21 detects a transition of the input signal DI and outputs a transition detecting signal s2 showing the transition of the input signal DI. The transition detecting circuit 21 includes: an inverter 211 for receiving the input signal DI; an inverter 212 for receiving an output of the inverter 211; and an XOR circuit 213 for receiving a signal s1 output from the inverter 212 and the input signal DI to output an XOR thereof as the transition detecting signal s2. The set/reset circuit 23 is set by the transition detecting signal s2 output from the transition detecting circuit 21 and reset by an inversion signal of the clock signal CK, that is, by an output of the inverter 22 to output the control signal EN.

When FIG. 1 is referred to again, the fuse 30 is connected between the control signal generating section 20 and the flip-flop circuits 10a and 10b. The fuse 30 is blown to shut off transmission of the control signal EN from the control signal generating section 20 to the flip-flop circuits 10a and 10b. Specifically, after the shipping inspection of a semiconductor product is completed, the fuse 30 is blown. In this way, it is possible to prevent the operation of the flip-flop circuits 10a and 10b even in the case of an erroneous control after the shipping.

The resistor 40 is connected between GND and a point connecting the fuse 30 to the flip-flop circuits 10a and 10b. When the control signal EN is in a high impedance state, the resistor 40 fixes the logic level of the control signal EN to “L”. The antifuse 50 is connected parallel to the fuse 30. The transmission of the control signal EN from the control signal generating section 20 to the flip-flop circuits 10a and 10b which has been shut off by blowing the fuse 30 is reconnected by the antifuse 50. Specifically, after the shipping of a semiconductor product, when it is required to perform the shipping inspection again, for example, to reinspect for defective products, the antifuse 50 is brought into a connected state. This allows the control signal EN to be transmitted from the control signal generating section 20 to the flip-flop circuits 10a and 10b, making it possible to perform the shipping inspection again.

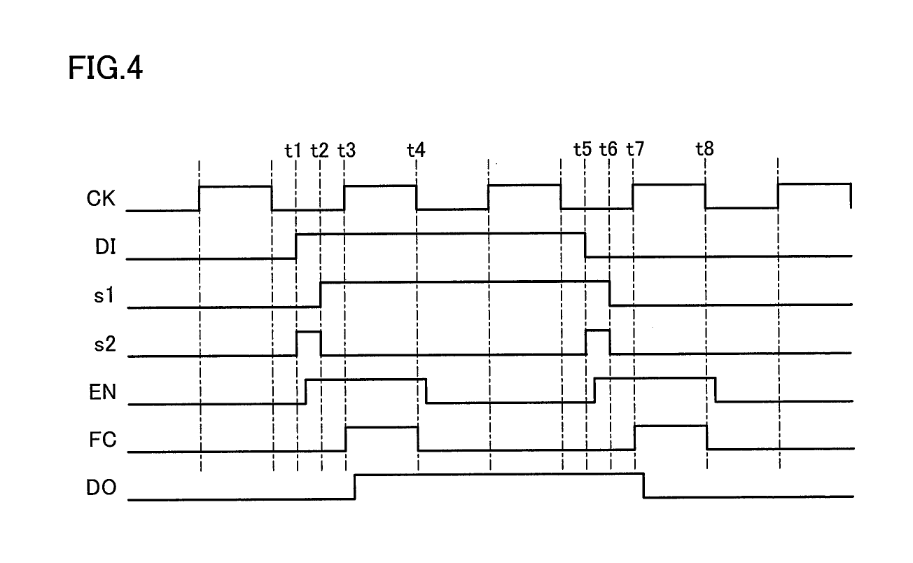

An operation of the semiconductor integrated circuit 1 in the case where data for the shipping inspection is given as the input signal DI will be described below. FIG. 4 is a timing chart of the semiconductor integrated circuit 1. At a time t1, the logic level of input data DI transitions from “L” to “H”, which causes the logic level of the transition detecting signal s2 output from the XOR circuit 213 to transition from “L” to “H”. Subsequently, the logic level of the control signal EN transitions from “L” to “H”. The input signal DI is delayed by the inverters 211 and 212, which causes the logic level of the transition detecting signal s2 to transition from “H” to “L” at a time t2. When the clock signal CK falls at a time t4, the logic level of the control signal EN transitions from “H” to “L”. The logic level of the signal FC output from the AND circuit 11 transitions from “L” to “H” at a rising timing of the clock signal CK immediately after the detection of the transition of the logic level of the input signal DI (time t1), that is, at a time t3. The input signal DI is latched at the rising timing of the signal FC at the time t3, and then the logic level of the output signal DO transitions from “L” to “H”.

Moreover, at a time t5, the logic level of the input signal DI transitions from “H” to “L”, which causes the logic level of the transition detecting signal s2 to transition from “L” to “H”. After this, the logic level of the control signal EN also transitions from “L” to “H”. The logic level of the signal FC output from the AND circuit 11 transitions from “L” to “H” at a time t7. After the rise of the signal FC, the logic level of the output signal DO transitions from “L” to “H”.

As described above, according to the present embodiment, it is possible to turn off a latch circuit whose operation is not required, so that the power consumption can be reduced. Moreover, since a common clock signal is supplied to all flip-flop circuits, one clock tree suffices. Even in the case where the number of operating conditions of the flip-flop circuits increases, the number of clock trees does not increase. Therefore, designing a circuit is facilitated and it is possible to reduce the man-hour required for the designing.

It is to be noted that the control signal generating section 20 may be a register which is accordingly rewritable from “H” to “L” and vice versa by CPU according to the operating conditions of the flip-flop circuits. Moreover, the control signal EN may be input externally, and in this case, the control signal generating section 20 can be omitted.

Moreover, in the present embodiment, one control signal generating section 20 is provided with the flip-flop circuits used for the same application. However, the control signal generating section 20 is not independently provided but may be provided inside each of the flip-flop circuits. In this case, each flip-flop circuit receives the input signal DI and the clock signal CK. Alternatively, in the case where the flip-flop circuits have different functions, the control signal generating section 20 may be provided for each of the flip-flop circuits.

Moreover, if the flip-flop circuits are used for a normal operation or the like and it is not especially required to turn off the flip-flop circuits continuously, the fuse 30 and the resistor 40 may be omitted. Moreover, if there is no need to reconnect the circuit which is once shut off by blowing the fuse, the antifuse 50 may be omitted.

### INDUSTRIAL APPLICABILITY

In the semiconductor integrated circuit according to the present invention, the power consumption can be reduced without increasing the number of clock trees. Therefore, the semiconductor integrated circuit according to the present invention is useful as a semiconductor integrated circuit including a plurality of circuits having different operating conditions.

1. A semiconductor integrated circuit comprising:
one or more flip-flop circuits each having a logic circuit for receiving a clock signal and a control signal and performing a logical operation on the clock signal and the control signal and a latch circuit for latching an input signal in synchronization with an output of the logic circuit; and
a control signal generating section for generating the control signal,
wherein the control signal generating section includes:
a transition detecting circuit for receiving the input signal and for outputting a transition detecting signal showing that the logic level of the input signal is transitioned; and
a set/reset circuit which is set by the transition detecting signal on one hand and reset by a reversed phase of the clock signal input to the logic circuit on the other hand to output the control signal.

2. (canceled)

3. The semiconductor integrated circuit of claim 1, further comprising:
a fuse connected between the logic circuit and the control signal generating section; and
a resistor connected between a reference voltage node and a point connecting the fuse to the logic circuit.

4. The semiconductor integrated circuit of claim 3, further comprising an antifuse connected parallel to the fuse.
